(19) United States
(12) Patent Application Publication
(10) Pub. No.: US 2025/0294865 A1
(43) Pub. Date: Sep. 18, 2025

(54) SEMICONDUCTOR DEVICES HAVING INTRINSIC GATE-TO-DRAIN CAPACITANCES THAT ARE ONLY PARTLY IN SERIES WITH A GATE RESISTOR

(71) Applicant: Wolfspeed, Inc., Durham, NC (US)

(72) Inventors: Rahul R. Potera, Apex, NC (US); Pushkar Saraf, Austin, TX (US)

(21) Appl. No.: 18/607,712

(22) Filed: Mar. 18, 2024

(51) Int. Cl. H01L 27/06; H01L 29/06; H01L 29/16; H01L 29/808

(52) U.S. Cl. CPC H10D 84/811; H10D 1/47; H10D 30/831; H10D 62/127; H10D 62/8325

(57) ABSTRACT

Power JFETs are provided that include a semiconductor layer structure that has an active region and a termination region, where the termination region at least partially surrounds the active region. These power JFETs further comprise a plurality of gate regions and a gate pad on the semiconductor layer structure, as well as a gate resistor that is electrically connected between the gate pad and the gate regions. The gate resistor extends around a periphery of the active region when the semiconductor device is viewed in plan view.

### FIELD

The present invention relates to semiconductor devices and, more particularly, to power semiconductor devices having gate resistors.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A power JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the power JFET may include, for example, a gate bond pad that serves as the gate terminal, a gate pad that is connected to the gate bond pad, a plurality of gate regions, and one or more gate buses, gate contact regions, gate contacts and/or gate electrodes that electrically connect the gate pad to the gate regions. The gate regions are disposed adjacent the respective channel regions. Power JFETs are typically normally-on devices, meaning that a JFET conducts current when a voltage of 0 volts is applied to the gate structure.

In order to convert a silicon carbide-based power JFET from a normally-on device to a normally-off device, a low-power MOSFET (which is typically an inexpensive silicon-based MOSFET) may be coupled to the power JFET in a cascode configuration to form an integrated normally-off JFET switch. FIG. 1 is a circuit diagram of such an integrated normally-off JFET switch 1 that includes a high-power JFET 10 cascoded with a low-power normally-off MOSFET 30. As shown in FIG. 1, the gate terminal G_{MOS} of the MOSFET 30 acts as the gate terminal G_{SW} of the switch 1, the source terminal S_{MOS} of the MOSFET 30 acts as the source terminal S_{SW} of the switch 1, and the drain terminal D_{JFET} of the JFET 10 acts as the drain terminal D_{SW} of the switch 1. The source terminal S_{JFET} of the JFET 10 is coupled to the drain terminal D_{MOS} of the MOSFET 30 at a center node M, and the gate terminal G_{JFET} of the JFET 10 is coupled to the source terminal S_{MOS} of the MOSFET 30. Herein, a high-power JFET such as JFET 10 that is cascoded with a normally-off MOSFET such as MOSFET 30 may be referred to as an integrated normally-off JFET switch. When the MOSFET 30 is turned off, the drain terminal D_{MOS} of the MOSFET 30, and hence the source terminal S_{JFET} of the JFET 10, may be at a large positive voltage, which would mean that the gate terminal G_{JFET} of the JFET relative to the source terminal S_{JFET} of the JFET may be at a large negative voltage (e.g., −30 volts). This large negative voltage acts to keep the JFET 10 from conducting. When the MOSFET 30 is turned on, the drain terminal D_{MOS} of the MOSFET 30, and hence the source terminal S_{JFET} of the JFET 10, may be at a voltage of near zero, allowing the JFET 10 to turn on. Thus, the integrated normally-off JFET switch 1 of FIG. 1 will operate as a normally-off device that turns on by applying a voltage to the gate terminal G_{MOS} of the MOSFET 30 that exceeds a threshold voltage of the MOSFET 30.

The gate structure of the power JFET 10 has a distributed gate resistance, which is a function of the length of the electrical path from the gate bond pad (or other gate terminal) to the gate regions of the individual unit cells, the lengths of the gate regions, and the sheet resistance of the materials forming the gate structure. It may be desirable to increase the gate resistance of an integrated normally-off JFET switch such as switch 1, as the increased gate resistance may reduce voltage overshoots at the drain terminal D_{SW} of the integrated normally-off JFET switch 1 that may occur during switching transients by damping the gate-to-source loop of the JFET 10. The increased gate resistance may also improve the behavior of the integrated normally-off JFET switch 1 during avalanche breakdown conditions. Thus, as shown in FIG. 1, the gate resistance may be increased by inserting a lumped gate resistor R_{G} (e.g., a surface mount resistor) in the electrical path between the source terminal S_{MOS} of the MOSFET 30 and the gate terminal G_{JFET} of the JFET 10. The lumped gate resistor R_{G} may also improve the electromagnetic interference (“EMI”) performance of the device.

### SUMMARY

Pursuant to some embodiments of the present invention, semiconductor devices are provided that comprise a semiconductor layer structure that comprises an active region and a termination region, a plurality of gate regions in the active region, a gate pad on the semiconductor layer structure, a gate bus that is electrically connected to the gate pad, and a gate resistor that is interposed between the gate bus and at least some of the gate regions when the semiconductor device is viewed in plan view.

In some embodiments, the gate resistor extends fully along at least two sides of the active region when the semiconductor device is viewed in plan view. In some embodiments, the semiconductor device further comprises a termination resistor that extends around a periphery of the gate bus when the semiconductor device is viewed in plan view. In some embodiments, the gate bus is directly connected to the gate pad, and the gate resistor is electrically interposed between the gate bus and the gate regions.

In some embodiments, the semiconductor device comprises a JFET having a JFET gate terminal, a JFET source terminal and a JFET drain terminal. In some embodiments, the JFET comprises a silicon carbide-based JFET and the semiconductor device is provided in combination with a silicon-based MOSFET and the silicon carbide-based JFET is cascoded with the silicon-based MOSFET.

In some embodiments, the semiconductor device is provided in combination with a transistor having a transistor gate terminal, a transistor source terminal and a transistor drain terminal, where the transistor source terminal is coupled to the JFET gate terminal and the transistor drain terminal is coupled to the JFET source terminal. In some embodiments, the JFET comprises a silicon carbide-based JFET and the transistor comprises a silicon-based MOSFET.

In some embodiments, an intrinsic gate-to-drain capacitance of the JFET comprises an active region gate-to-drain capacitance and a termination region gate-to-drain capacitance, and wherein the active region gate-to-drain capacitance is electrically in series with the gate resistor and the termination region gate-to-drain capacitance is not electrically in series with the gate resistor. In some embodiments, the termination region gate-to-drain capacitance is electrically in parallel with the gate resistor. In some embodiments, the intrinsic gate-to-drain capacitance of the JFET further comprises a gate pad/bus region gate-to-drain capacitance that is electrically in parallel with the gate resistor.

In some embodiments, the semiconductor layer structure includes a drift region having a first conductivity type and a patterned region that has a second conductivity type on the drift region, where the gate resistor is formed in a portion of the patterned region. In some embodiments, the semiconductor layer structure further comprises a channel region having the first conductivity type on the drift region, where a first conductivity type dopant concentration of the channel region exceeds a first conductivity type dopant concentration of the drift region, and wherein the patterned region is at least partially formed within the channel region. The semiconductor layer structure may further comprise a source region having the first conductivity type on the channel region, where a first conductivity type dopant concentration of the source region exceeds a first conductivity type dopant concentration of the channel region, and the semiconductor device further comprises a source contact on the semiconductor layer structure and one or more gate insulating patterns that separate the gate regions from the source contact.

In some embodiments, the gate pad and the gate bus are each formed directly on the patterned region. In some embodiments, the gate pad comprises a metal gate pad region and a metal silicide gate pad region, the gate bus comprises a metal gate bus region and a metal silicide gate bus region, and the gate resistor comprises a portion of the patterned region that has an upper surface that is devoid of any metal silicide. In some embodiments, an upper portion of the semiconductor layer structure in the active region comprises a plurality of trenches and the gate regions are in sidewalls of the respective trenches. In some embodiments, the semiconductor device further comprises a plurality of gate contact regions that are underneath the respective trenches, and a plurality of gate contacts that are in the respective trenches.

In some embodiments, the gate contact regions are part of the patterned region.

In some embodiments, the gate bus is interposed between the gate resistor and the termination resistor. In some embodiments, the gate pad is also interposed between the gate resistor and the termination resistor.

Pursuant to further embodiments of the present invention, semiconductor devices are provided that comprises a semiconductor layer structure that comprises an active region, a gate pad/bus region and a termination region, a plurality of gate regions, a gate pad on the gate pad/bus region of the semiconductor layer structure, and a gate resistor that is electrically connected between the gate pad and the gate regions. An intrinsic gate-to-drain capacitance of the semiconductor device comprises an active region gate-to-drain capacitance, a gate pad/bus region gate-to-drain capacitance and a termination region gate-to-drain capacitance, and the active region gate-to-drain capacitance is electrically coupled in series with the gate resistor and the termination region gate-to-drain capacitance is not electrically coupled in series with the gate resistor.

In some embodiments, the termination region gate-to-drain capacitance is electrically coupled in parallel with the gate resistor.

In some embodiments, the semiconductor device further comprises a gate bus that is electrically connected to the gate pad, the gate resistor is electrically interposed between the gate bus and at least some of the gate regions. In some embodiments, the semiconductor device further comprises a termination resistor that extends around a periphery of the gate bus when the semiconductor device is viewed in plan view. In some embodiments, the gate bus and the gate pad are both interposed between the gate resistor and the termination resistor when the semiconductor device is viewed in plan view. In some embodiments, the gate pad/bus region gate-to-drain capacitance is electrically in parallel with the gate resistor and the termination resistor.

In some embodiments, the semiconductor device comprises a silicon carbide-based JFET having a JFET gate terminal, a JFET source terminal and a JFET drain terminal, and the semiconductor device is provided in combination with a silicon-based MOSFET that comprises a MOSFET gate terminal, a MOSFET source terminal and a MOSFET drain terminal, where the MOSFET source terminal is coupled to the JFET gate terminal and the MOSFET drain terminal is coupled to the JFET source terminal.

In some embodiments, the semiconductor layer structure includes a drift region having a first conductivity type and a patterned region that has a second conductivity type on the drift region, where the gate resistor is formed in a portion of the patterned region. In some embodiments, the gate pad and the gate bus are each formed directly on the patterned region, wherein the gate pad comprises a metal gate pad region and a metal silicide gate pad region and the gate bus comprises a metal gate bus region and a metal silicide gate bus region, and wherein the gate resistor comprises a portion of the patterned region that has an upper surface that is devoid of any metal silicide.

In some embodiments, the gate regions are in sidewalls of respective ones of a plurality of trenches in the active region of the semiconductor layer structure.

Pursuant to still further embodiments of the present invention, semiconductor devices are provided that comprise a semiconductor layer structure, a plurality of gate regions in the semiconductor layer structure, a gate pad on the semiconductor layer structure, a gate bus on the semiconductor layer structure, and a gate resistor in the semiconductor layer structure. The gate pad is directly electrically connected to the gate bus, and the gate resistor is electrically interposed between the gate bus and at least some of the gate regions.

In some embodiments, the semiconductor device further comprises a termination resistor that extends around a periphery of the gate bus when the semiconductor device is viewed in plan view. In some embodiments, both the gate pad and the gate bus are interposed between the gate resistor and the termination resistor when the semiconductor device is viewed in plan view.

In some embodiments, the semiconductor device comprises a silicon carbide-based JFET having a JFET gate terminal, a JFET source terminal and a JFET drain terminal, and the semiconductor device is provided in combination with a silicon-based MOSFET that comprises a MOSFET gate terminal, a MOSFET source terminal and a MOSFET drain terminal, and wherein the MOSFET source terminal is coupled to the JFET gate terminal and the MOSFET drain terminal is coupled to the JFET source terminal. In some embodiments, the semiconductor layer structure includes an active region, a gate pad/bus region and a termination region, the termination region at least partially surrounding the active region.

In some embodiments, an intrinsic gate-to-drain capacitance of the JFET comprises an active region gate-to-drain capacitance and a termination region gate-to-drain capacitance, and wherein the active region gate-to-drain capacitance is electrically in series with the gate resistor and the termination region gate-to-drain capacitance is not electrically in series with the gate resistor. In some embodiments, the termination region gate-to-drain capacitance is electrically in parallel with the gate resistor. In some embodiments, the intrinsic gate-to-drain capacitance of the JFET further comprises a gate pad/bus region gate-to-drain capacitance that is electrically in parallel with the gate resistor.

Pursuant to additional embodiments of the present invention, semiconductor devices are provided that comprise a semiconductor layer structure comprising an active region that comprises a plurality of unit cell JFETs and a termination region, a gate pad on the semiconductor layer structure and a gate bus on the semiconductor layer structure. The semiconductor layer structure further comprises a plurality of gate regions that are electrically connected to the gate pad through the gate bus and a gate resistor that is electrically connected to the gate bus and a termination resistor that is interposed between the gate bus and the termination region when the semiconductor device is viewed in plan view.

In some embodiments, an intrinsic gate-to-drain capacitance of the semiconductor device comprises an active region gate-to-drain capacitance and a termination region gate-to-drain capacitance, and wherein the active region gate-to-drain capacitance is electrically in series with the gate resistor and the termination region gate-to-drain capacitance is not electrically in series with the gate resistor. In some embodiments, the termination region gate-to-drain capacitance is electrically in parallel with the gate resistor. In some embodiments, the termination region gate-to-drain capacitance is electrically in series with the termination resistor.

In some embodiments, the intrinsic gate-to-drain capacitance of the JFET further comprises a gate pad/bus region gate-to-drain capacitance that is electrically in parallel with the series combination of the gate resistor and the active region gate-to-drain capacitance. In some embodiments, the gate pad/bus region gate-to-drain capacitance is electrically in parallel with the series combination of the termination resistor and the termination region gate-to-drain capacitance.

Pursuant to yet additional embodiments of the present invention, semiconductor devices are provided that comprise a semiconductor layer structure comprising an active region that comprises a plurality of unit cell JFETs and a termination region, a plurality of gate regions in the semiconductor layer structure, where at least some of the gate regions extend from a first side of the active region to an opposed second side of the active region, and a gate resistor on the semiconductor layer structure that extends along both the first and second sides of the active region.

In some embodiments, the semiconductor device further comprises a gate pad on the semiconductor layer structure and a gate bus on the semiconductor layer structure, and the gate bus is electrically connected to at least some of the gate regions through the gate resistor.

In some embodiments, the gate regions are in sidewalls of respective ones of a plurality of trenches in the active region.

### BRIEF DESCRIPTION OF DRAWINGS

FIG. 1 is a circuit diagram of an integrated normally-off JFET switch that comprises a high-power JFET and a low-power MOSFET in cascode configuration.

FIG. 2 is a circuit diagram of an integrated normally-off JFET switch of FIG. 1 that illustrates the locations of various intrinsic capacitances of the JFET and MOSFET.

FIG. 3 is a circuit diagram of an integrated normally-off JFET switch according to embodiments of the present invention.

FIG. 4A is a schematic plan view of a power JFET according to embodiments of the present invention that may be used in an integrated normally-off JFET switch.

FIGS. 4B-4D are schematic cross-sectional diagrams taken along lines B-B, C-C and D-D of FIG. 4A, respectively.

FIG. 5 is a circuit diagram of the power JFET of FIGS. 4A-4D.

FIGS. 6-9 are schematic plan views of power JFETs according to further embodiments of the present invention that may be used in an integrated normally-off JFET switch.

### DETAILED DESCRIPTION

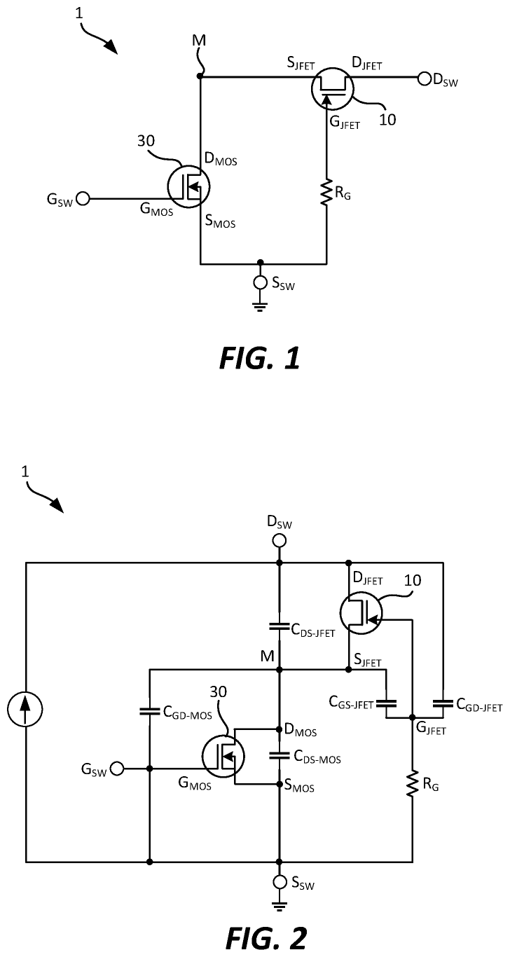

Power JFETs may be desirable for certain applications because they have high current carrying capability, high reliability, and may be formed using a simpler process than a comparably-rated power MOSFET. Moreover, as discussed above, a power JFET can be converted from a normally-on device to a normally-off device by connecting an inexpensive, low-voltage MOSFET in cascode configuration to the power JFET to provide an integrated normally-off JFET switch. However, when a power JFET is cascaded with a MOSFET, voltage overshoot may occur during switching at a “center node” M (see FIG. 1) where the source terminal S_{JFET} of the JFET 10 connects to the drain terminal D_{MOS} of the MOSFET. This voltage overshoot can exert reverse voltage overstress on the gate-source of the JFET 10. Reverse voltage overstress can push the power JFET beyond the maximum voltage rating for the gate structure of the JFET, which can affect reliability. The reverse voltage overstress can also push the low-voltage MOSFET to avalanche breakdown conditions, and the low-voltage MOSFET may not be rated to sustain avalanche breakdown conditions for significant time periods and, even if it is, the low-voltage MOSFET may not be rated to sustain avalanche breakdown conditions many times as would happen if it was pushed into avalanche breakdown during every turn-off switching cycle. Thus, the amount of voltage overshoot may need to be tightly controlled.

The amount of the voltage overshoot is a function of the gate resistance of the JFET, with the voltage overshoot increasing with increasing gate resistance. The slope of the drain voltage (dV_{D}/dt) of the integrated normally-off JFET switch during device turn-off is also a function of the gate resistance, with higher gate resistances reducing dV_{D}/dt. It is desirable to keep dV_{D}/dt low because the higher the dV_{D}/dt during turn-off the more the voltage overshoot at the drain terminal. The voltage overshoot that is beyond the rail voltage may need to be limited to a maximum voltage rating of the device. For example, if a device rated for 750 volts is used at a 400 volt rail application, at a certain dV_{D}/dt overshoot it will reach 750 volts and that will limit dV_{D}/dt. In addition to voltage overshoot, higher dV_{D}/dt may also cause electromagnetic interference at higher frequencies which may need to be limited for statutory compliance reasons depending on the end-use application. Thus, there is an inherent tradeoff between the voltage overshoot at the center node M (see FIG. 1) and the dV_{D}/dt performance of an integrated normally-off JFET switch. As discussed above, power JFETs typically include a lumped gate resistor R_{G} that is used to increase the gate resistance of the device. This lumped gate resistor R_{G} often is the vast bulk of the gate resistance, so in the discussion that follows the focus is on the lumped gate resistor R_{G}.

The present invention is based, in part, on the realization that the impact of the gate resistor R_{G} on the voltage overshoot at the center node M is a function of the current that flows through the intrinsic gate-to-drain capacitance C_{GDJ} of the JFET and into the gate resistor R_{G} as the MOSFET is turned off. Consequently, if the intrinsic gate-to-drain capacitance C_{GDJ} can be reduced, then less current will flow into the gate resistor R_{G} for the same dV_{D}/dt, since the current I equals C_{GDJ}*dV_{D}/dt.

The intrinsic gate-to-drain capacitance C_{GDJ} of the JFET 10 is a function of the size of the JFET 10 and the design thereof. Generally speaking, JFETs are designed to have low gate-to-drain capacitance values. Thus, the value of C_{GDJ} typically cannot be readily reduced without negatively impacting other performance parameters of the JFET such as the current handling capability of the JFET. If the gate resistance of an integrated normally-off JFET switch is increased by adding an off-chip gate resistor R_{G}, the gate resistor R_{G} is necessarily electrically in series with the full intrinsic gate-to-drain capacitance C_{GDJ} of the JFET. However, if the gate resistor R_{G} is implemented as part of the JFET, then it is possible to design the JFET so that a portion of the gate-to-drain capacitance C_{GDJ} of the JFET is not disposed in series with the gate resistor R_{G}. The portion of the gate-to-drain capacitance C_{GDJ} of the JFET that is not disposed in series with the gate resistor R_{G} will not feed current to the gate resistor R_{G} during device turn-off, and hence will not contribute to voltage overshoot at the center node M, and hence voltage overshoot at turn-off is reduced for the same value of the gate resistance. Moreover, since the gate resistor R_{G} is fully within the gate-to-source loop of the JFET, the gate resistor R_{G} has its full effect on dV_{D}/dt when the JFET turns off as it would if a portion of the intrinsic gate-to-drain capacitance of the JFET C_{GDJ} had not been diverted to not be in series with the gate resistor R_{G}. Thus, through this technique, it is possible to reduce voltage overshoot at the center node M without increasing dV_{D}/dt when the JFET turns off.

Pursuant to embodiments of the present invention, integrated normally-off JFET switches are provided that may have improved voltage overshoot performance without sacrificing the dV_{D}/dt performance when the JFET turns off. This improved voltage overshoot performance is achieved by diverting a portion of the intrinsic gate-to-drain capacitance C_{GDJ} of the JFET so that it is not in series with an on-chip gate resistor R_{G} of the JFET. In some embodiments, the portion of the intrinsic gate-to-drain capacitance C_{GDJ} of the JFET that is diverted to not be in series with a gate resistor R_{G} of the JFET is the portion of the gate-to-drain capacitance C_{GDJ} that corresponds to a termination region of the JFET. In other embodiments, the portion of the intrinsic gate-to-drain capacitance C_{GDJ} that is diverted to not be in series with a gate resistor R_{G} of the JFET is the portion of the gate-to-drain capacitance C_{GDJ} that corresponds to a gate pad/bus region of the JFET that includes the gate pad and the gate bus. In still other embodiments, the portion of the intrinsic gate-to-drain capacitance C_{GDJ} that is diverted to not be in series with a gate resistor R_{G} of the JFET may be both the portion of the gate-to-drain capacitance C_{GDJ} that corresponds to the termination region and the portion of the gate-to-drain capacitance C_{GDJ} that corresponds to the gate pad/bus region.

The portions of the intrinsic gate-to-drain capacitance C_{GDJ} that correspond to the gate pad/bus and/or termination regions of the JFET may be diverted so that they do not feed current to the gate resistor R_{G} by designing the JFET so that the gate resistor Ro is not along the current path between the gate pad/gate bus and drain of the JFET. In some embodiments, this may be accomplished by having the on-chip gate resistor R_{G} extend around much of the active region of the JFET when the JFET is viewed in plan view. For example, the gate resistor R_{G} may extend fully along at least two sides of the active region. The gate bus may be connected to the gate pad so that the gate pad and gate bus extend around the gate resistor R_{G}. A gate signal applied to the gate pad may pass to the gate bus and flow around the periphery of the active region of the JFET, and may pass from the gate bus through the gate resistor R_{G} to gate contacts and then to gate contact regions that feed the gate regions in the active region of the JFET. An electrical path is provided from the gate pad to the termination region of the device that does not extend through the gate resistor. As such, the contributions to the intrinsic gate-to-drain capacitance C_{GDJ} that are provided by the gate pad/bus and termination regions of the JFET are not provided in series with the gate resistor.

In some embodiments, power JFETs are provided that include a semiconductor layer structure that has an active region and a termination region, where the termination region at least partially surrounds the active region. These power JFETs further comprise a plurality of gate regions and a gate pad on the semiconductor layer structure, as well as a gate resistor that is electrically connected between the gate pad and the gate regions. The gate resistor extends around a periphery of the active region when the power JFET is viewed in plan view.

In other embodiments, power JFETs are provided that include a semiconductor layer structure that has an active region, a gate pad/bus region and a termination region. A plurality of gate regions are provided in sidewalls of respective ones of a plurality of trenches in the active region of the semiconductor layer structure. A gate pad is provided on the gate region of the semiconductor layer structure, and a gate bus is electrically connected to the gate pad. A gate resistor is interposed between the gate bus and at least some of the gate regions when the semiconductor device is viewed in plan view. An intrinsic gate-to-drain capacitance of the JFET comprises an active region gate-to-drain capacitance, a gate pad/bus region gate-to-drain capacitance and a termination region gate-to-drain capacitance, and the active region gate-to-drain capacitance is electrically coupled in series with the gate resistor and the termination region gate-to-drain capacitance is not electrically coupled in series with the gate resistor.

In still other embodiments, power JFETs are provided that comprise a semiconductor layer structure, and a plurality of gate regions, as well as a gate pad, a gate bus and a gate resistor on the semiconductor layer structure. The gate pad is directly electrically connected to the gate bus, and the gate resistor is electrically interposed between the gate bus and at least some of the gate regions.

In yet additional embodiments, semiconductor devices are provided that comprise a semiconductor layer structure comprising an active region that comprises a plurality of unit cell junction field effect transistors (“JFETs”) and a termination region that at least partly extends around the active region, a gate pad on the semiconductor layer structure and a gate bus on the semiconductor layer structure. The semiconductor layer structure further comprises a plurality of gate regions that are electrically connected to the gate pad through the gate bus and a gate resistor that is electrically connected to the gate bus and a termination resistor that is interposed between the gate bus and the termination region when the semiconductor device is viewed in plan view.

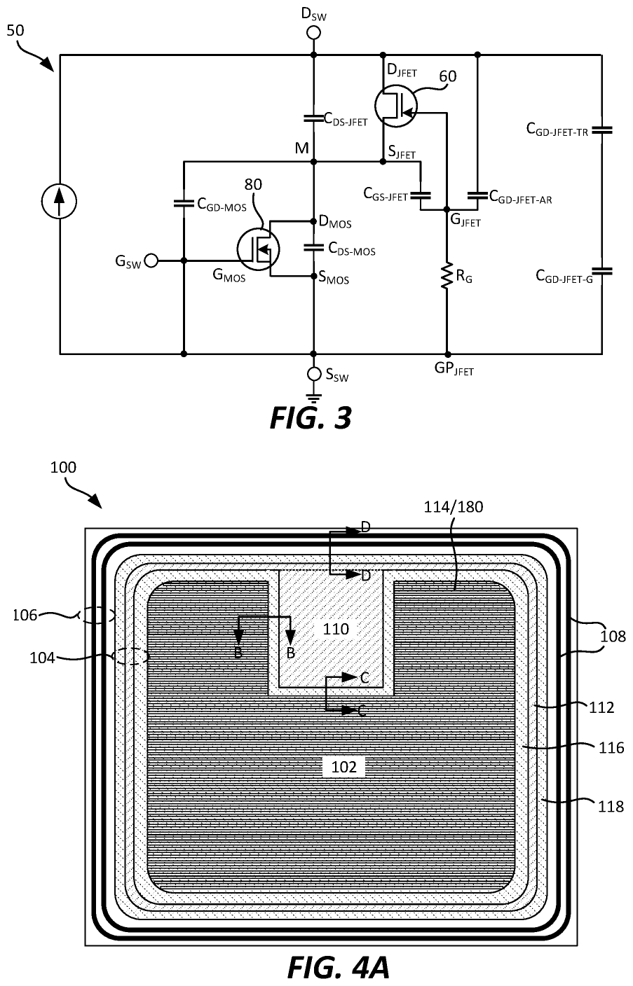

Embodiments of the present invention will now be discussed in greater detail with reference to FIGS. 2-9.

FIG. 2 is a circuit diagram of the integrated normally-off JFET switch 1 of FIG. 1 that illustrates the locations of various intrinsic capacitances of the JFET 10 and the MOSFET 30 that are included in the integrated normally-off JFET switch 1. As shown in FIG. 2, the power JFET 10 includes an on-chip gate resistor R_{G}, and also includes an intrinsic gate-to-source capacitance C_{GS-JFET}, an intrinsic gate-to-drain capacitance C_{GD-JFET}, and an intrinsic drain-to-source capacitance C_{DS-JFET}, while the MOSFET includes an intrinsic drain-to-source capacitance C_{DS-MOS} and an intrinsic gate-to-drain capacitance C_{GD-MOS}. Notably, all of the current that flows through the intrinsic gate-to-drain capacitance C_{GD-JFET} flows into the on-chip gate resistor R_{G} as the MOSFET 30 and JFET 10 turn off, and it is this current that results in the voltage overshoot at the center node M.

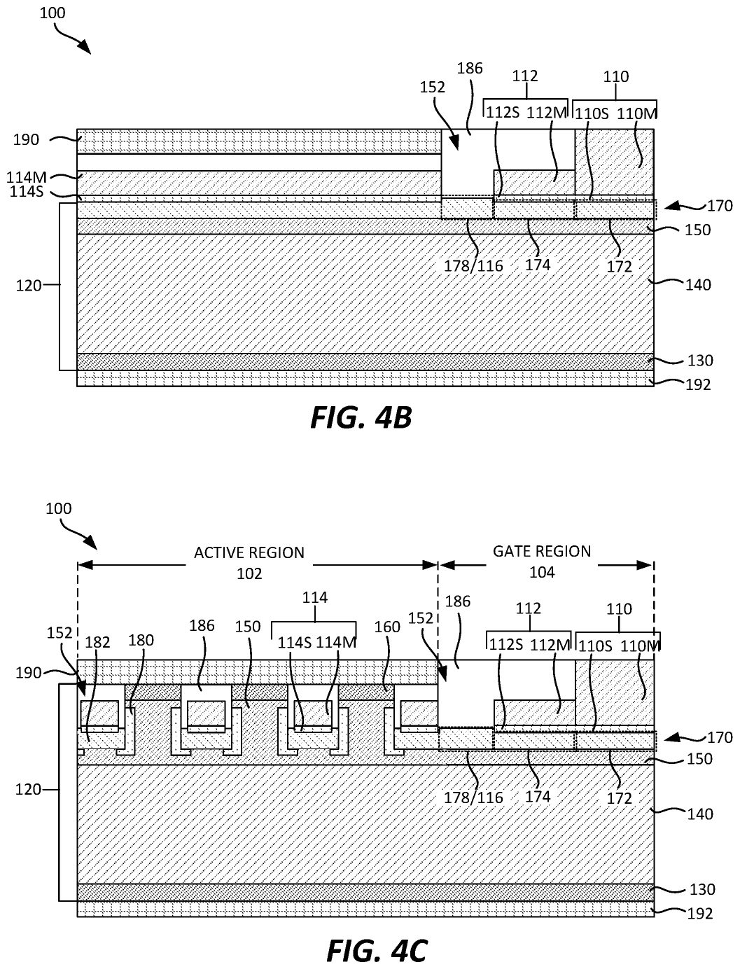

Embodiments of the present invention are based, in part, on the realization that the intrinsic gate-to-drain capacitance C_{GD-JFET} of the JFET includes three portions, namely (1) the intrinsic gate-to-drain capacitance in the active region C_{GD-JFET-AR} which primarily results from the capacitive coupling between the gates/gate contact regions/gate electrodes and the drain region/terminal, (2) the intrinsic gate-to-drain capacitance in the gate pad/bus region C_{GD-JFET-G} which primarily results from the capacitive coupling between the gate pad/gate bus and the drain region/terminal, and (3) the intrinsic gate-to-drain capacitance in the termination region C_{GD-JFET-TR} which primarily results from the capacitive coupling between the edge of the gate pad/bus region and the drain region/terminal in a lateral direction across the termination region. While the on-chip gate resistor R_{G} necessarily needs to be electrically in series with the intrinsic gate-to-drain capacitance in the active region C_{GD-JFET-AR} (since the on-chip gate resistor R_{G} needs to be in the gate-source loop of the JFET in order to slow dV_{D}/dt), the intrinsic gate-to-drain capacitance in the gate pad/bus region C_{GD-JFET-G} and the intrinsic gate-to-drain capacitance in the termination region C_{GD-JFET-TR} need not be in the gate-source loop of the JFET. Accordingly, the JFET may be designed so that one or both of these intrinsic capacitances C_{GD-JFET-G}, C_{GD-JFET-TR} are not electrically in series with the on-chip gate resistor R_{G}. This is shown schematically in FIG. 3, which is a circuit diagram of an integrated normally-off JFET switch 50 according to embodiments of the present invention that includes a JFET 60 that is cascaded with a MOSFET 80. As shown in FIG. 3, an on-chip gate resistor R_{G} (i.e., a gate resistor that is implemented within the power JFET semiconductor die) is interposed between a gate pad GP_{JFET} of the JFET 60 and the gate regions G_{JFET} of the JFET 60. As can be seen by comparing FIGS. 2 and 3, the integrated normally-off JFET switch 50 is similar to the integrated normally-off JFET switch 10 of FIG. 2. However, integrated normally-off JFET switch 50 includes an on-chip as opposed to an off-chip gate resistor R_{G} and a first portion of the intrinsic gate-to-drain capacitance C_{GD-JFET} is provided in series with this on-chip lumped gate resistor R_{G} while the remainder of the intrinsic gate-to-drain capacitance C_{GD-JFET} is provided in parallel to the on-chip gate resistor R_{G} (and hence not electrically in series with the on-chip lumped gate resistor R_{G}).

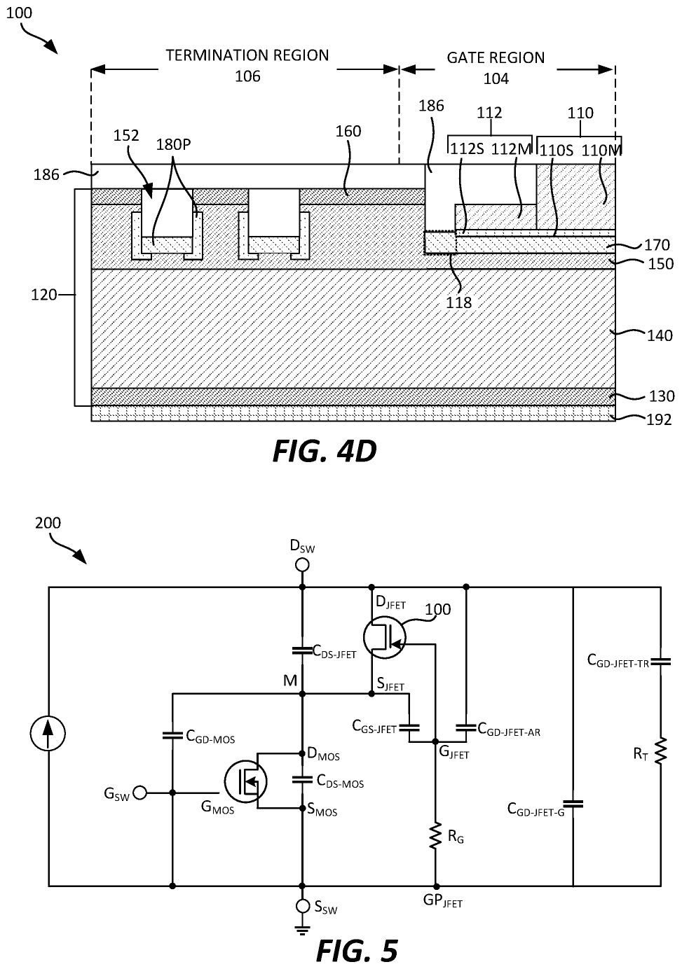

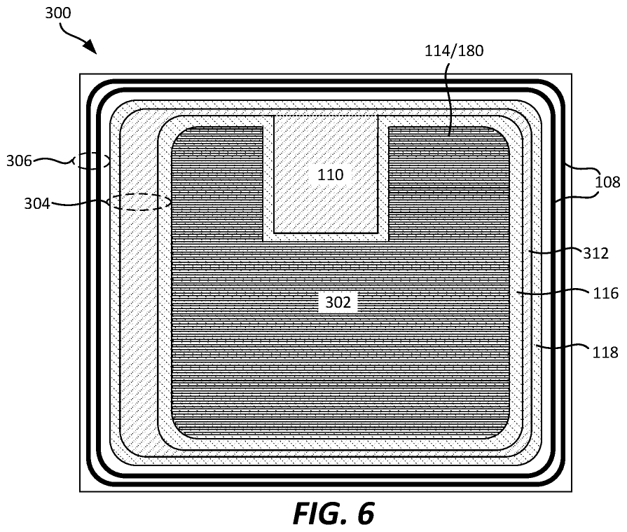

FIG. 4A is a schematic plan view of a power JFET 100 according to embodiments of the present invention that may be used in an integrated normally-off JFET switch according to embodiments of the present invention. In FIG. 4A, several of the upper layers of the JFET 100 including the source and gate bond pads, the source contact, the gate insulating patterns and the upper passivation/protection patterns are omitted to better show the gate structure of the power JFET 100. FIGS. 4B-4D are schematic cross-sectional diagrams taken along lines B-B, C-C and D-D of FIG. 4A, respectively. To provide additional context, the source contact 190 and the gate insulating patterns 186 that are omitted in FIG. 4A are shown in FIGS. 4B, 4C and/or 4D, although the other layers discussed above are still omitted in FIGS. 4B-4D.

Referring first to FIG. 4A, the power JFET 100 includes an active region 102, a gate pad/bus region 104, and a termination region 106. The active region 102 is the portion of the power JFET 100 that acts as a main junction for blocking voltage during off-state operation and current flows through the active region 102 during on-state operation. The power JFET 100 may have a unit cell structure such that a large number of individual “unit cell” JFETs are formed in the active region 102 and electrically connected in parallel to each other so that the unit cells together function as a single power JFET 100. The gate pad/bus region 104 is the region corresponding to a gate pad 110, a gate bus 112 and a gate resistor 116. An ellipse labelled 104 in FIG. 4A identifies a small portion of the gate pad/bus region 104, but it will be appreciated that the gate pad/bus region 104 extends all of the way around the active region 102 and also includes the gate pad 110. The gate pad 110 may comprise a metal pad and may be provided underneath a metal gate bond pad (not shown) if a separate metal gate bond pad is provided. In other embodiments, the gate pad may comprise other materials (e.g., polysilicon). The metal gate bond pad (or the gate pad 110 if no metal gate bond pad is provided) may be connected to an external circuit (e.g., to a MOSFET of an integrated normally-off JFET switch) through bond wires, leads or other electrical connections. The gate pad 110 provides an electrical connection between the metal gate bond pad (or the external circuit) and the gate bus 112. The gate bus 112 may be a high conductivity bus that carries gate signals from the gate pad 110 to a plurality of gate contacts 114 that are provided in the active region 102. The gate bus 112 may comprise a metal or may comprise other materials (e.g., polysilicon). The gate contacts 114 feed a plurality of gate regions 180 (discussed below) that are in the active region 102 through respective gate contact regions 182. The gate regions 180 may, for example, be within side surfaces of the respective gate trenches 152, the gate contact regions 182 may be in the bottom surfaces of the respective gate trenches 152, and the gate contacts 114 may be formed in the gate trenches on the gate contact regions 182. As shown in FIG. 4A, the gate pad 110 and the gate bus 112 may be formed as a single integral (monolithic) pattern. The edge termination region 106 is a region that at least partially surrounds the active region 102 and the gate pad/bus region 104. The edge termination region 106 is designed to spread the electric fields during reverse blocking operation out over a greater area in order to reduce electric field crowding effects that would otherwise occur along the outer edges of the active region 102. An ellipse labelled 106 in FIG. 4A identifies a small portion of the termination region 106, but it will be appreciated that the termination region 106 extends all of the way around the gate pad/bus region 104.

As is further shown in FIG. 4A, power JFET 100 also includes an on-chip lumped gate resistor 116 (which corresponds to gate resistor R_{G} in FIG. 3) that is interposed on the electrical path between the gate pad/gate bus 110/112 and the gate contacts 114, gate contact regions 182 and gate regions 180. The on-chip lumped gate resistor 116 may have a gate resistance in a range of about 5 ohms to about 50 ohms in example embodiments. It will be appreciated, however, that the resistance value may be adjusted based on the application. The on-chip lumped gate resistor 116 may extend around the periphery of the active region 102 when the power JFET 100 is viewed in plan view (i.e., from above) and may surround the active region 102 in plan view. The combination of the gate pad 110 and the gate bus 112 may extend around the periphery of the on-chip lumped gate resistor 116 when the power JFET 100 is viewed in plan view (i.e., from above) and may surround the on-chip lumped gate resistor 116 in plan view. The edge termination region 106 may extend around the periphery of the gate pad 110 and gate bus 112 when the power JFET 100 is viewed in plan view.

Power JFET 100 further includes a termination resistor 118. The termination resistor 118 may extend around the periphery of the gate bus 112 and may surround the gate bus 112 when the power JFET 100 is viewed in plan view. The termination resistor 118 may separate the termination region 106 from the gate pad/bus region 104.

The termination region 106 may include one or more termination structures. In the depicted embodiment, the termination region 106 includes two guard rings 108, which are p-type regions that are formed as rings around the active region. The number and type of termination structures included in the termination region 106 may be changed from that which is shown in FIG. 4A. For example, the guard rings 108 could be replaced with a junction termination extension.

Referring to FIGS. 4B-4D, the power JFET 100 includes a semiconductor layer structure 120. The semiconductor layer structure 120 may include a substrate 130, a drift region 140, a channel region 150, source regions 160, a patterned region 170, and gate regions 180.

The substrate 130 may be formed of wide bandgap semiconductor materials (e.g., may be a silicon carbide substrate) and may be heavily doped with n-type (n+) dopants in example embodiments. The substrate 130 may have a doping concentration of 1×10¹⁸ to 1×10²¹ dopants/cm³ in example embodiments. The drift region 140 may be provided on an upper surface of the substrate 130. The drift region 140 may be formed of wide bandgap semiconductor materials (e.g., may be an epitaxially grown silicon carbide layer) and may be a lightly-doped n-type (n⁻) region. The drift region 140 may have, for example, a doping concentration of 1×10¹⁴ to 1×10¹⁷ dopants/cm³ in example embodiments. The drift region 140 may be a thick region, having a vertical height above the substrate 130 of, for example, 3-100 microns. While not shown in FIGS. 4B-4D, in some embodiments an upper portion of the drift region 140 may be more heavily doped (e.g., a doping concentration of 1×10¹⁶ to 2×10¹⁷ dopants/cm³) than the lower portion thereof to provide a current spreading layer in the upper portion of the drift region 140.

The channel region 150 is provided on an upper surface of the drift region 140. The channel region 150 may be formed of wide bandgap semiconductor materials (e.g., epitaxially grown silicon carbide) and may be a moderately doped n-type (n) region. The channel region 150 may have a doping concentration higher than the doping concentration of the lower portion of the drift region 140. For example, a doping concentration of the channel region 150 may be between 1×10¹⁶ to 1×10¹⁷ dopants/cm³.

The source regions 160 may be provided on an upper surface of the channel region 150. The source regions 160 may be formed of wide bandgap semiconductor materials (e.g., epitaxially grown silicon carbide) and may be heavily-doped n-type (n+) regions. The source regions 160 may have a doping concentration higher than that of the channel region 150 and may have, for example, a doping concentration of 1×10¹⁹ to 5×10²⁰ dopants/cm³.

A plurality of trenches 152 are formed in the semiconductor layer structure 120 using, for example, one or more etching processes. The trenches 152 may be formed in the channel region 150 and the source regions 160 in the active region 102, the gate pad/bus region 104 and the termination region.

The patterned region 170 may be formed of wide bandgap semiconductor materials (e.g., silicon carbide) and may be a heavily-doped p-type (p+) region. The patterned region 170 may be formed, for example, by implanting p-type dopants through the bottoms of the respective trenches 152 so as to convert selected portions of the channel region 150 into p-type semiconductor material. The patterned region 170 may have, for example, a doping concentration of 1×10¹⁹ to 5×10²⁰ dopants/cm³. The patterned region 170 may be a continuous region or a plurality of discontinuous regions.

The portions of the patterned region 170 that are within the active region 102 comprise gate contact regions 182, Accordingly, the gate contact regions 182 comprise p-type wide bandgap semiconductor materials (e.g., silicon carbide). Each gate contact region 182 may have relatively high doping concentrations such as, for example, a doping concentration of 1×10¹⁹ to 2×10²⁰ dopants/cm³. The gate contact regions 182 may be formed by ion implantation into the bottoms of the trenches 152. The gate contact regions 182 are underneath the trenches 152 and may form the bottoms of the trenches 152.

The gate regions 180 may also be provided in the channel region 150. The gate regions 180 may be formed of wide bandgap semiconductor materials (e.g., silicon carbide) and may be p-type regions. Each gate region 180 may form a portion of a sidewall of a respective one of the trenches 152. The gate regions 180 may have a lower doping concentration than the gate contact regions 182. For example, each gate region 180 may have a doping concentration of 1×10¹⁷ to 1×10¹⁸ dopants/cm³. The gate regions 180 may be formed, for example, by performing an angled ion implantation process to implant p-type dopants into the sidewalls of the trenches 152.

In some embodiments, the drift region 140, the channel region 150 and the source regions 160 may all be formed by one or more epitaxial growth processes using the substrate 130 as a seed layer. As discussed above, the patterned region 170 (including gate contact regions 182) and the gate regions 180 may be formed by implanting p-type dopants into selected portions of the channel region 150.

The patterned region 170 may include a gate pad portion 172, a gate bus portion 174, the gate contact regions 182, a gate resistor portion 178 and a termination resistor portion 179. The gate resistor portion 178 may implement the on-chip lumped gate resistor 116 and the termination resistor portion 17 may implement the termination resistor 118.

The gate pad portion 172 of the patterned region 170 is interposed between the channel region 150 and the gate pad 110 and may contact both the channel region 150 and the gate pad 110. The gate bus portion 174 of the patterned region 170 is interposed between the channel region 150 and the gate bus 112 and may contact both the channel region 150 and the gate bus 112. The gate contact regions 182 of the patterned region 170 electrically connect the gate contacts 114 to the gate regions 180 and may contact the channel region 150.

The gate pad 110 and the gate bus 112 are provided on the semiconductor layer structure 120. In example embodiments, the gate pad 110 may comprise a metal silicide gate pad region 110S and a metal gate pad 110M that are sequentially stacked on the gate pad portion 172 of the patterned region 170. An upper surface of the gate pad portion 172 of the patterned region 170 may contact the metal silicide gate pad region 110S. In example embodiments, the gate bus 112 may comprise a metal silicide gate bus region 112S and a metal gate bus 112M that likewise are sequentially stacked on the gate bus portion 174 of the patterned region 170. An upper surface of the gate bus portion 174 of the patterned region 170 may contact the metal silicide gate bus region 112S. The gate pad 110 and the gate bus 112 may each be at least partially disposed in one of the trenches 152 that are formed in the upper surface of the semiconductor layer structure 120 in some embodiments.

Each unit cell JFET in the active region 102 includes a gate region 180, a gate contact region 182 and a gate contact 114. Each gate contact 114 may comprise a metal silicide region 114. An additional metal gate electrode 115 may optionally be provided on each gate contact 114. Each metal silicide gate contact 114 and any associated metal gate electrode 115 (if provided) may be sequentially stacked on a respective one of the gate contact regions 182 of the patterned region 170. Upper surfaces of the gate contact regions 182 of the patterned region 170 may contact the respective metal silicide gate contacts 114. Each gate contact 114 may be provided at least partially in a respective one of a plurality of trenches 152 that are formed in the upper surface of the semiconductor layer structure 120.

As the drift region 140, the channel region 150 and the source regions 160 have the same conductivity type (e.g., n-type), each unit cell of the power JFET 100 is normally on and is turned off when a sufficient negative gate bias relative to the source is applied to the gate pad 110 or when the voltage at the JFET source terminal S_{JFET} is brought to a sufficiently high level relative to the gate.

The metal silicide gate pad region 110S, the metal silicide gate bus region 112S, the metal silicide gate contacts 114 and any metal gate electrodes 115 provide a very low resistance electrical path from the metal gate pad 110M to the gate contacts 114. The gate contacts 114 provide low resistivity paths above each gate contact region 182 so that the gate signal may spread throughout the active region 102 through the gate contacts 114 and then pass to the gate contact regions 182 along the lengths thereof. The gate signal then flows from the gate contact regions 182 to the gate regions 180. The metal silicide gate pad region 110S, the metal silicide gate bus region 112S and the metal silicide gate contacts 114 may be formed of metal silicide (e.g., nickel silicide, tungsten silicide, titanium silicide or molybdenum silicide). In some embodiments, the metal silicide gate pad region 110S, the metal silicide gate bus region 112S and the metal silicide gate contacts 114 may be formed of nickel silicide. The metal gate pad 110M, the metal bus 112M, and the metal gate electrodes 114 (if provided) may be formed of metal (e.g., aluminum, tungsten, nickel, titanium, ruthenium and/or an alloy thereof).

As shown in FIGS. 4B-4C, the gate resistor 116 may be electrically interposed between the gate pad 110 and the gate bus 112 (e.g., between the metal gate pad 110M and the metal gate bus 112M), and a current flowing between the gate pad 110 and the gate bus 112 may flow through the gate resistor 116. An upper surface of the gate resistor 116 may be devoid of a silicide region. The resistance of the gate resistor 116 may be at least several orders of magnitude greater than the resistance of the gate pad 110 and the gate bus 112 in example embodiments.

The power JFET device 100 may also include gate insulating patterns 186 that are provided on the metal gate bus 112M, the metal gate electrodes 115 (or on the metal silicide gate contacts 114, if the gate electrodes 115 are not provided), the gate resistor 116 and the termination resistor 118. The gate insulating patterns 186 may comprise, for example, one or more dielectric materials such as silicon oxide, silicon nitride, silicon oxynitride or the like.

A source contact 190 may be provided on the source regions 160 and the gate insulating patterns 186. The source contact 190 may include one or more layers such as, for example, a diffusion barrier layer and a bulk metal layer. The gate insulating patterns 186 may insulate the metal gate bus 112M and the gate contacts 114 from the source contact 190.

A drain pad 192 (e.g., a metal drain pad) may be provided on the bottom side of the power JFET 100. The drain pad 192 may be connected to an underlying submount such as a lead frame, a heat sink, a power substrate or the like via soldering, brazing, direct compression or the like.

Referring to FIG. 4D, it can be seen that gate-like structures 180P are formed in the termination region 106 that include p-type regions that may be identical to the gate regions 180 discussed above. Notably, structures similar to the gate contacts 114 and the optional gate electrodes 115 are omitted in the termination region 106. Unlike the gate regions 180 and the gate contact regions 182, the gate-like structures 180P that are provided in the termination region are electrically floating and are only capacitively coupled to each other and to the gate on one side and the drain on the other. Thus, the p-type regions 180P may act as guard rings that help reduce electric field crowding effects that may otherwise occur at edges of the active region 102. As can also be seen in FIG. 4D, the termination resistor 118 is not electrically connected to anything other than to the capacitance to drain from the edge of the gate. In addition, the source metal 190 is omitted in the termination region 106 and may be replaced with or more insulating layers 186.

Referring to FIGS. 4A-4D, it can be seen that according to some embodiments of the present invention, semiconductor devices such as power JFET 100 are provided that include a semiconductor layer structure 120 that has an active region 102 and a termination region 106. The termination region 106 may at least partially surround the active region 102. The power JFET 100 further comprise a gate pad 110 and a gate bus that is electrically connected to the gate pad 110 on the semiconductor layer structure 120. The semiconductor device further comprises a plurality of gate regions 180, as well as a gate resistor 116 that is interposed between the gate bus 112 and at least some of the gate regions 180 when the power JFET 100 is viewed in plan view.

In some embodiments, the gate resistor 116 extends fully along at least two sides of the active region when the power JFET 100 is viewed in plan view.

In some embodiments, the power JFET 100 may also include a termination resistor 118. The termination resistor 118 may extend around a periphery of the gate bus 112 when the power JFET 100 is viewed in plan view. The gate bus 112 may be directly connected to the gate pad 110 (and may be monolithic with the gate pad 110). In some embodiments, the gate bus 112 may be interposed between the gate resistor 116 and the termination resistor 118. In some embodiments, the gate pad 110 may also be interposed between the gate resistor 116 and the termination resistor 118.

In some embodiments, the power JFET 100 may be provided in combination with a silicon-based MOSFET (or other transistor) and the silicon carbide-based JFET is cascoded with the silicon-based MOSFET.

In some embodiments, the active region gate-to-drain capacitance C_{GD-JFET-AR} is electrically in series with the gate resistor R_{G} and the termination region gate-to-drain capacitance C_{GD-JFET-TR} is not electrically in series with the gate resistor R_{G}. For example, the termination region gate-to-drain capacitance C_{GD-JFET-TR} may be electrically in parallel with the gate resistor R_{G}. In some embodiments, the gate pad/bus region gate-to-drain capacitance C_{GD-JFET-G} may not be in series with the gate resistor R_{G}. In some embodiments, neither the termination region gate-to-drain capacitance C_{GD-JFET-TR} nor the gate pad/bus region gate-to-drain capacitance C_{GD-JFET-G} may be in series with the gate resistor R_{G}.

In some embodiments, the semiconductor layer structure 120 includes a drift region 140 having a first conductivity type (e.g., n-type) and a patterned region 170 that has a second conductivity type (e.g., p-type) on the drift region 140, where the gate resistor 116 is formed in a portion of the patterned region 170. The semiconductor layer structure 120 may further comprise a channel region 150 having the first conductivity type (e.g., n-type) on the drift region 140, where a first conductivity type dopant concentration of the channel region 150 exceeds a first conductivity type dopant concentration of the drift region 140. The patterned region 170 may be at least partially formed within the channel region 150.

The semiconductor layer structure 120 may also comprise a source region 160 having the first conductivity type on the channel region 150. A first conductivity type dopant concentration of the source region 160 may exceed a first conductivity type dopant concentration of the channel region 150. The power JFET 100 may also comprise a source contact 190 on the semiconductor layer structure 120 and one or more gate insulating patterns 186 that separate the gate regions 180, gate contact regions 182 and gate contacts 114/gate electrodes 115 from the source contact 190. The gate pad 110 and the gate bus 112 may each be formed directly on the patterned region 170 in some embodiments.

The gate pad 110 may comprise a metal gate pad region 110M and a metal silicide gate pad region 110S and the gate bus 112 may comprise a metal gate bus region 112M and a metal silicide gate bus region 112S. The gate resistor 116 may comprise a portion of the patterned region 170 that has an upper surface that is devoid of any metal silicide. The gate regions 180 may be formed the sidewalls of the respective trenches 152 and the gate contact regions 182 may form the bottoms of the respective trenches 152.

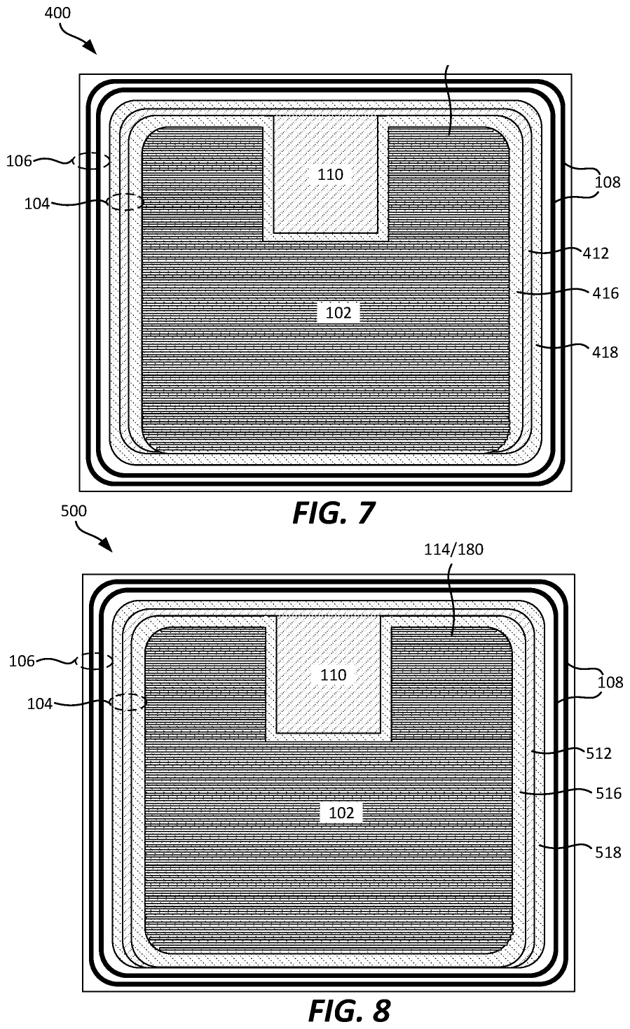

FIG. 5 is a circuit diagram of an integrated normally-off JFET switch 200 that includes the power JFET 100 of FIGS. 4A-4D. As shown in FIG. 5, the on-chip gate resistor 116 of power JFET 100 is interposed between the gate pad 110/gate bus 112 (GP_{FET}) and the gate regions 180 (G_{FET}). The portion of the intrinsic gate-to-drain capacitance C_{GD-JFET-AR} that is contributed by the active region comprises the coupling between the gate regions 180, gate contact regions 182 and gate contacts 114 and the drain contact 192. As shown in FIG. 5, the portion of the intrinsic gate-to-drain capacitance that is contributed by the active region C_{GD-JFET-AR} is electrically in series with the gate resistor 116 so that current discharged from the intrinsic gate-to-drain capacitance C_{GD-JFET-AR} at device turn-off flows through the gate resistor 116.

As is also shown in FIG. 5, the intrinsic gate-to-drain capacitance C_{GD-JFET-G} that is contributed by the gate pad/bus region 104 is not electrically in series with the gate resistor 116 but instead is coupled electrically in parallel to the gate resistor 116. As such, current that is discharged from the intrinsic gate-to-drain capacitance C_{GD-JFET-G} at device turn-off does not flow through the gate resistor 116 and hence does not contribute to increasing voltage overshoot at the center node M during device turn-off.

Still referring to FIG. 5, the intrinsic gate-to-drain capacitance C_{GD-JFET-TR} that is contributed by the termination region also is not electrically in series with the gate resistor 116. Instead, the intrinsic gate-to-drain capacitance C_{GD-JFET-TR} is coupled electrically in parallel to the gate resistor 116. As such, current that is discharged from the intrinsic gate-to-drain capacitance C_{GD-JFET-TR} at device turn-off does not flow through the gate resistor 116 and hence does not contribute to increasing voltage overshoot at the center node M during device turn-off. The termination resistor RT/118 is coupled in series with the intrinsic gate-to-drain capacitance C_{GD-JFET-TR}.

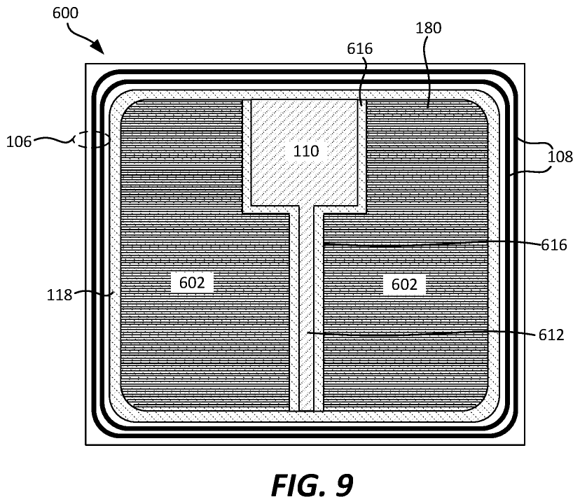

FIGS. 6-9 are schematic plan views of power JFETs according to further embodiments of the present invention. In these figures, the gate insulating patterns and the upper passivation/protection layers are omitted as was done in FIG. 4A.

FIG. 6 is a schematic plan view of a power JFET 300 according to further embodiments of the present invention that may be used in an integrated normally-off JFET switch. As can be seen by comparing FIG. 6 to FIG. 4A, the power JFET 300 is very similar to the power JFET 100, except that in power JFET 300 a portion of the gate bus 312 (see left side of FIG. 6) has an increased size which acts to increase the portion of the intrinsic gate-to-drain capacitance C_{GD-JFET-G} that is contributed by the gate pad/bus region 304 (with a corresponding reduction in the portion of the intrinsic gate-to-drain capacitance C_{GD-JFET-AR} that is contributed by the active region 302). In this manner the dVD/dt performance of the power JFET 300 may be kept constant while the voltage overshoot performance may be further increased since the portion of the intrinsic gate-to-drain capacitance C_{GD-JFET-AR} that is contributed by the active region 302 is reduced. However, this improvement in performance comes at the cost of a reduction in the size of the active region 302 which negatively impacts the voltage blocking and current handling capabilities of power JFET 300 as compared to power JFET 100. It will be appreciated that in other embodiments the size of the termination region 306 could be increased instead of the size of the gate bus to provide a similar improvement in voltage overshoot performance.

FIG. 7 is a schematic plan view of a power JFET 400 according to still further embodiments of the present invention. The power JFET 400 may be used, for example, in an integrated normally-off JFET switch. As can be seen by comparing FIG. 7 to FIG. 4A, the power JFET 400 is similar to the power JFET 100, except that the gate bus 112 and the gate resistor 116 of power JFET 100 are replaced in power JFET 400 with a gate bus 412 and a gate resistor 416. The gate bus 412 and gate resistor 416 extend along the upper portion of the active region 102 (as shown in the view of FIG. 7) as well as along both sides of the active region 102, but do not extend along the lower portion of the active region 102. The design of FIG. 7 takes advantage of the fact that the gate bus 412 connects to each gate contacts 114 along the sides of the active region 102 and thus there is no need to have the gate bus 412 and the gate resistor 416 extend along the lower side of the active region 102. This design allows the size of the active region 102 to be increased since the gate bus 412 and the gate resistor 416 need not extend along the lower side of the active region 102.

FIG. 8 is a schematic plan view of a power JFET 500 according to still further embodiments of the present invention that is similar to the power JFET 400 of FIG. 7. As can be seen, the only difference between power JFET 400 and power JFET 500 is that power JFET 400 has a termination resistor 418 extend along the lower side of the active region 102 and the gate resistor 416 does not extend along the lower side of the active region 102, while in power JFET 500 the gate resistor 516 extends along the lower side of the active region 102 and the termination region 518 does not extend along the lower side of the active region 102.

FIG. 9 is a schematic plan view of a power JFET 600 according to still further embodiments of the present invention. Power JFET 600 uses a different gate bus approach to feed the gate regions. As shown in FIG. 9, a gate bus 612 extends through the center of the active region 602, thereby dividing the active region 602 into two spaced-apart regions. A two-part (distributed) gate resistor 616 is provided that is positioned in between the gate pad/gate bus 110/612 and the gate regions 180. Power JFET 600 may have the equivalent circuit that is shown in FIG. 5.

While the semiconductor devices discussed above are n-type devices, it will be appreciated that in p-type devices these locations are reversed and that this invention applies to both n-type and p-type devices. Moreover, while the above-described power semiconductor devices and the other devices described herein are shown as being silicon carbide-based semiconductor devices, it will be appreciated that embodiments of the present invention are not limited thereto. Instead, the semiconductor devices may comprise any wide bandgap semiconductor that is suitable for use in power semiconductor devices including, for example, gallium nitride-based semiconductor devices, gallium nitride-based semiconductor devices and II-VI compound semiconductor devices.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure that comprises a termination region and an active region that comprises a plurality of gate regions;
a gate pad on the semiconductor layer structure;
a gate bus that is electrically connected to the gate pad; and
a gate resistor that is interposed between the gate bus and at least some of the gate regions when the semiconductor device is viewed in plan view.

2. The semiconductor device of claim 1, wherein the gate resistor extends fully along at least two sides of the active region when the semiconductor device is viewed in plan view.

3. The semiconductor device of claim 2, further comprising a termination resistor that extends around a periphery of the gate bus when the semiconductor device is viewed in plan view.

4. (canceled)

5. The semiconductor device of claim 1, wherein the semiconductor device comprises a junction field effect transistor (“JFET”) having a JFET gate terminal, a JFET source terminal and a JFET drain terminal.

6. The semiconductor device of claim 5, wherein the JFET comprises a silicon carbide-based JFET and the semiconductor device is provided in combination with a silicon-based metal-oxide-semiconductor field-effect transistor (“MOSFET”) and the silicon carbide-based JFET is cascoded with the silicon-based MOSFET.

7-8. (canceled)

9. The semiconductor device of claim 5, wherein an intrinsic gate-to-drain capacitance of the JFET comprises an active region gate-to-drain capacitance and a termination region gate-to-drain capacitance, and wherein the active region gate-to-drain capacitance is electrically in series with the gate resistor and the termination region gate-to-drain capacitance is not electrically in series with the gate resistor.

10. (canceled)

11. The semiconductor device of claim 9, wherein the intrinsic gate-to-drain capacitance of the JFET further comprises a gate pad/bus region gate-to-drain capacitance that is electrically in parallel with the gate resistor.

12. The semiconductor device of claim 1, wherein the semiconductor layer structure includes a drift region having a first conductivity type and a patterned region that has a second conductivity type on the drift region, where the gate resistor is formed in a portion of the patterned region.

13. The semiconductor device of claim 12, wherein the semiconductor layer structure further comprises a channel region having the first conductivity type on the drift region, where a first conductivity type dopant concentration of the channel region exceeds a first conductivity type dopant concentration of the drift region, and wherein the patterned region is at least partially formed within the channel region.

14. (canceled)

15. The semiconductor device of claim 12, wherein the gate pad and the gate bus are each formed directly on the patterned region.

16. The semiconductor device of claim 15, wherein the gate pad comprises a metal gate pad region and a metal silicide gate pad region, the gate bus comprises a metal gate bus region and a metal silicide gate bus region, and the gate resistor comprises a portion of the patterned region that has an upper surface that is devoid of any metal silicide.

17-18. (canceled)

19. The semiconductor device of claim 12, wherein the gate contact regions are part of the patterned region.

20-21. (canceled)

22. A semiconductor device, comprising:
a semiconductor layer structure that comprises an active region, a gate pad/bus region and a termination region;
a plurality of gate regions;
a gate pad on the gate pad/bus region of the semiconductor layer structure; and
a gate resistor that is electrically connected between the gate pad and the gate regions,
wherein an intrinsic gate-to-drain capacitance of the semiconductor device comprises an active region gate-to-drain capacitance, a gate pad/bus region gate-to-drain capacitance and a termination region gate-to-drain capacitance, and
wherein the active region gate-to-drain capacitance is electrically coupled in series with the gate resistor and the termination region gate-to-drain capacitance is not electrically coupled in series with the gate resistor.

23. (canceled)

24. The semiconductor device of claim 22, further comprising a gate bus that is electrically connected to the gate pad, the gate resistor is electrically interposed between the gate bus and at least some of the gate regions.

25. The semiconductor device of claim 24, further comprising a termination resistor that extends around a periphery of the gate bus when the semiconductor device is viewed in plan view.

26. The semiconductor device of claim 25, wherein the gate bus and the gate pad are both interposed between the gate resistor and the termination resistor when the semiconductor device is viewed in plan view.

27-31. (canceled)

32. A semiconductor device, comprising:
a semiconductor layer structure;
a plurality of gate regions in the semiconductor layer structure;
a gate pad on the semiconductor layer structure;
a gate bus on the semiconductor layer structure; and
a gate resistor in the semiconductor layer structure,
where the gate pad is directly electrically connected to the gate bus, and the gate resistor is electrically interposed between the gate bus and at least some of the gate regions.

33. The semiconductor device of claim 32, further comprising a termination resistor that extends around a periphery of the gate bus when the semiconductor device is viewed in plan view.

34. The semiconductor device of claim 33, wherein both the gate pad and the gate bus are interposed between the gate resistor and the termination resistor when the semiconductor device is viewed in plan view.

35. The semiconductor device of claim 32, wherein the semiconductor device comprises a silicon carbide-based junction field effect transistor (“JFET”) having a JFET gate terminal, a JFET source terminal and a JFET drain terminal, and the semiconductor device is provided in combination with a silicon-based metal-oxide-semiconductor field-effect transistor (“MOSFET”) that comprises a MOSFET gate terminal, a MOSFET source terminal and a MOSFET drain terminal, and wherein the MOSFET source terminal is coupled to the JFET gate terminal and the MOSFET drain terminal is coupled to the JFET source terminal.

36. The semiconductor device of claim 35, wherein the semiconductor layer structure includes an active region, a gate pad/bus region and a termination region, the termination region at least partially surrounding the active region.

37. The semiconductor device of claim 36, wherein an intrinsic gate-to-drain capacitance of the JFET comprises an active region gate-to-drain capacitance and a termination region gate-to-drain capacitance, and wherein the active region gate-to-drain capacitance is electrically in series with the gate resistor and the termination region gate-to-drain capacitance is not electrically in series with the gate resistor.

38. The semiconductor device of claim 37, wherein the termination region gate-to-drain capacitance is electrically in parallel with the gate resistor.

39-51. (canceled)
